(19) United States
(12) Patent Application Publication
(10) Pub. No.: US 2026/0304680 A1
(43) Pub. Date: Oct. 1, 2026

(54) SEPARATE CONTAINER AND SEPARATELY CONTAINERIZED SERVER DEVICE

(71) Applicant: CANAAN CREATIVE CO., LTD., Beijing (CN)

(72) Inventors: Guanchao Zhao, Beijing (CN); Nan Li, Beijing (CN); Shishuang He, Beijing (CN); Zonghai Chen, Beijing (CN); Xiaogang Sun, Beijing (CN); Xiaoye Zhao, Beijing (CN); He Ying, Beijing (CN); Nangeng Zhang, Beijing (CN)

(21) Appl. No.: 19/479,390

(22) PCT Filed: Mar. 7, 2024
(86) PCT No.: PCT/CN2024/080556

§ 371 Date: Oct. 28, 2025

(30) Foreign Application Priority Data
Apr. 28, 2023 (CN) 202321024380.3
May 17, 2023 (CN) 202321201967.7

(51) Int. Cl. H05K 7/14

(52) U.S. Cl. CPC H05K 7/1497

(57) ABSTRACT

Disclosed are a separate container and a separately containerized server device. The separate container in the present application comprises a container body, a rack and an electric control system, wherein the rack and the electric control system are both fixed in the container body, and the container body is provided with a connecting portion for connecting two adjacent separate containers. The present application allows for customized combination according to a user's specific requirements and geographic environment scenarios, so as to meet different requirements of different users at different stages, quickly respond to changes in the user's requirements, and reduce the device investment and waste, and thereby achieving high flexibility and strong security, improving the working efficiency, and reducing investment costs.

### CROSS-REFERENCE TO RELATED APPLICATIONS

The present application claims priority to Chinese Patent Application No. 202321024380.3 filed on Apr. 28, 2023, and priority to Chinese Patent Application No. 202321201967.7 filed on May 17, 2023, and these patent applications are incorporated herein by reference for all purposes as if fully set forth herein.

### TECHNICAL FIELD

The present application relates to the field of computing devices, and specifically to a separate container and a separately containerized server device.

### BACKGROUND

A containerized server cluster refers to a server cluster formed by integrating a plurality of servers into a container or modular cabinet, which can be rapidly deployed and relocated. This approach can improve the density and efficiency of the servers, meet the rapidly growing demand for data processing, reduce energy consumption and costs, and provide flexibility and scalability.

How to make the containerized server cluster variably configured under different geographical conditions, power allocations, and computing power requirements is a technical problem that needs to be solved by those skilled in the art.

### SUMMARY

An objective of the present application is to provide a separate container to meet different requirements of users for the size, scale and computing power of containerized servers based on different geographical conditions and power allocations in each usage region, as well as different purposes and usage times of the users, or to meet changing requirements at different time periods.

Another objective of the present application is to provide a separately containerized server device including the above separate container.

In order to implement the above objectives, the separate container of the present application includes a container body having a connecting portion for connecting two adjacent separate containers. The connecting portion is used for connection and fixation when adjacent separate containers are assembled with each other.

The above separate container may be regarded as a dedicated container. The separate container of the present application includes a container body, a rack and an electric control system, the rack and the electric control system are respectively fixed in the container body, and the container body has a connecting portion for connecting two adjacent separate containers.

Regarding the above separate container, the connecting portion includes a plurality of length connecting components located at an end along a length direction of the container body, and/or the connecting portion includes a plurality of height connecting components located at an end along a height direction of the container body. The length connecting components are used for connection and fixation when adjacent separate containers are assembled with each other along the length direction, and the height connecting components are used for connection and fixation when adjacent separate containers are assembled with each other along the height direction.

The separate container of the present application may allow for customized combination according to a user's specific requirements and geographic environment scenarios, so as to meet different requirements of different users at different stages, quickly respond to changes in the user's requirements, and reduce the device investment and waste, and thereby achieving high flexibility and strong security, improving the working efficiency, and reducing investment costs.

Regarding the above separate container, the container body is provided with a communication port in communication with another container body disposed adjacently. By disposing the communication port, the adjacent separate containers can be in communication with each other.

Regarding the above separate container, the communication port is located at an end along the length direction and/or height direction of the container body, and the communication port is provided with a movable wall. During transportation or when communication is not required, the communication port is closed by the movable wall; and when communication is required, the movable wall may be removed or opened to make the adjacent separate containers in communication.

Regarding the above separate container, the movable wall includes a door and/or a detachable wall panel. When the door is opened, adjacent separate containers are in communication; and/or when the detachable wall panel is removed, adjacent separate containers are in communication.

Regarding the above separate container, the communication port is at an entire end position of the container body along the length direction. That is to say, an entire side face of the container body along the length direction is the communication port, and the position of the entire side face is provided as an openable/closable door or a detachable wall panel.

Regarding the above separate container, the connecting portion includes a container corner member. The separate container of the present application utilizes the characteristics of the corner member to use it as the connecting portion during assembly of the separate container, and adjacent separate containers are fixed through a container corner member connector.

Regarding the above separate container, an external size of length, width and height of the container body is smaller than a size of an internal space of a standard container, and the container body can be integrally loaded in the standard container. The separate container of the present application combines design compactness, high operational efficiency, high maintenance performance, high structural strength and high resistance to vibration and impact. Meanwhile, by designing the external size of length, width and height of the container body to be smaller than the size of the internal space of the standard container, the separate container of the present application can be integrally loaded in the standard container, thereby improving the safety in the transportation process and reducing losses.

Regarding the above separate container, when the container body is loaded in the standard container, a first gap and a second gap are present between left and right side walls of the container body along the length direction and left and right inner walls of the standard container along the length direction. Preferably, the first gap and the second gap are 45±10 mm.

Regarding the above separate container, a third gap and a fourth gap are respectively present between front and rear side walls of the container body along a width direction and front and rear inner walls of the standard container along the width direction. Preferably, the third gap and the fourth gap are 45±10 mm.

Regarding the above separate container, a fifth gap is present between a top wall of the container body and a top inner wall of the standard container. Preferably, the fifth gap is 40±10 mm.

The first to fifth gaps are used for providing a relative moving distance for the separate container to move when loaded in the standard container, and providing an assembly margin for manufacturing error, movement shaking, and minor deformation, so as to prevent the separate container from being unable to enter the standard container, or from being stuck and unable to move relatively in a loading process.

Regarding the above separate container, a maintenance passage is disposed in the container body, and an end of the container body in the length direction corresponding to the maintenance passage is provided with the movable wall. The maintenance passage is used for staff to conduct regular inspection, maintenance and upkeep for systems, devices, networks, and the like to ensure that they can normally operate, prevent failures and accidents, and improve the reliability and stability of the systems, and the movable wall is provided to allow the staff to enter the maintenance passage and to pass through maintenance passages when a plurality of separate containers are connected.

Regarding the above separate container, the communication port is located at an end along the height direction of the container body, and the communication port is provided with a movable wall. That is to say, a position in a container top and/or container bottom of the container body corresponding to an end of the maintenance passage is provided with the movable wall for internal communication when the separate containers are stacked up and down.

Regarding the above separate container, the communication port is provided with a ladder, by which upper and lower spaces are accessible. The ladder is preferably a foldable ladder, which may be unfolded when needed to be used and retracted when not needed, without occupying the space of the maintenance passage.

Regarding the above separate container, the electric control system is used for connecting with servers carried by the rack, and the electric control system includes a power distribution cabinet, the rack and the power distribution cabinet are disposed in a row along the length direction of the container body to form a device row, and the maintenance passage is formed between the device row and a side wall of the container body. The device row is provided to integrate a relatively large number of servers in an optimal spatial arrangement, and form a spacious and smooth maintenance passage, making full use of a space inside the container body.

Regarding the above separate container, positions of two side walls of the container body along the width direction not corresponding to the maintenance passage are provided with fixed side walls, which simplifies unnecessary design, and reduces safety hazards and the costs of maintenance and device manufacturing.

Regarding the above separate container, the container body includes a first side heat dissipation long edge and a second side heat dissipation long edge that are disposed oppositely, the first side heat dissipation long edge is provided with a dustproof mesh and/or shutters and/or a water curtain structure, the second side heat dissipation long edge is provided with a cooling structure, and the maintenance passage is disposed between the device row and the first side heat dissipation long edge. The present application employs air cooling for heat dissipation, which is a high-efficiency and low-consumption heat dissipation manner, resulting in a simple structure, low costs, and a good heat dissipation effect.

Regarding the above separate container, the cooling structure is disposed corresponding to a position of the rack, and a position on the second side heat dissipation long edge corresponding to the power distribution cabinet is provided with a maintenance door. When maintenance is required, the staff arrive at outside of a second long side edge of the container body, open the maintenance door facing the power distribution cabinet between the cooling structures, and then may directly walk into the container body to conduct professional work, such as cleaning, inspection, maintenance, replacement, and upgrading, on the power distribution cabinet. The power distribution cabinet has a built-in smart meter, which supports remote data reading.

Regarding the separate container, the cooling structure includes a fan and a fan mounting frame, and the fan is mounted to the container body through the fan mounting frame.

Regarding the above separate container, the fan mounting frame includes a connecting framework connected to the container body and a supporting frame detachably connected to an inner side or outer side of the connecting framework through a plurality of fasteners, and the fan is disposed on the supporting frame. The fan is connected to the inner side or outer side of the connecting framework through the supporting frame and may be placed an inner side or outer side of the container body, achieving switching between inside and outside placement of the fan to meet different heat dissipation needs in different regions.

Regarding the above separate container, the supporting frame includes a fixing portion for detachably connecting the connecting framework through a fastener and a supporting portion for supporting the fan, the supporting frame including a limiting portion for limiting displacement of the fan. The supporting frame is bent from a metal plate and machined to form the fixing portion, the supporting portion and the limiting portion, which is simple in machining and firm in structure.

Regarding the above separate container, the connecting framework is connected to at least one of a top side beam, a bottom side beam, and a corner post of the container body. The top side beam, the bottom side beam and the corner post structures of the container are utilized to mount the connecting framework, making the structure firm and not easy to deform.

Regarding the above separate container, a position on the first side heat dissipation long edge corresponding to the power distribution cabinet is provided with a protective wall, and a position on the first side heat dissipation long edge corresponding to the rack is provided with a dustproof mesh and/or shutters and/or a water curtain structure. The protective wall is made of, for example, a steel plate and the corner post. Part of the protective wall may be added with transverse and longitudinal reinforcing ribs to improve the overall strength of the container body, enhance the resistance of the container body to deformation and extrusion, and reduce the possibility of damage during loading, unloading and transportation.

Regarding the above separate container, it further includes a water curtain storage structure for storing the water curtain structure, and the water curtain storage structure is located in the container body. The container body is provided with the water curtain storage structure, an accessory box, and the like. During transportation, accessory facilities on the outer side of the container body are removed and fixed in the container body to ensure a minimized size of the container body.

The separately containerized server device of the present application includes a plurality of servers, and further includes the above separate container, and the servers are arranged and disposed on the rack and connected to the electric control system.

Regarding the above separately containerized server device, a plurality of separate containers are provided, and a plurality of container bodies are connected through connecting portions along a length direction and/or height direction of the container bodies. That is to say, the plurality of separate containers may be connected transversely to form a separately containerized server device, or the plurality of separate containers may be connected longitudinally to form a separately containerized server device, or they may be arranged and connected transversely and longitudinally to form a matrix-type separately containerized server device.

Regarding the above separately containerized server device, two adjoining separate containers are in internal communication therebetween along the length direction of the container bodies. Two adjoining separate containers are in internal communication therebetween along the height direction of the container bodies. A plurality of adjoining separate containers form a unitary internally-communicating whole.

Regarding the above separately containerized server device, a sealing structure is disposed in a slit between two separate containers adjoining each other along the length direction of the container bodies, which avoids dust, rainwater, etc. from entering into the container bodies and affecting the performance of the device.

The following detailed description of the present application will be made in conjunction with the drawings and specific embodiments, but is not intended to limit the present application.

### BRIEF DESCRIPTION OF THE DRAWINGS

FIG. 1 is a perspective structural diagram of an embodiment of a separate container of the present application;

FIG. 2 is a front view of an embodiment of a separate container of the present application (with parts disposed on the first side heat dissipation long edge not shown);

FIG. 3 is a top view of an embodiment of a separate container of the present application (with the top plate of the container body not shown);

FIG. 4 is a perspective structural diagram of an embodiment of a separate container combination of the present application;

FIG. 5 is a top view of an embodiment of a separate container combination of the present application (with the top plates of the container bodies not shown);

FIG. 6 is a perspective structural diagram of an embodiment of a corner member connector employed when separate containers of the present application are combined;

FIG. 7 is a perspective structural diagram of an embodiment of a separate container combination of the present application;

FIG. 8 is a perspective structural diagram of an embodiment of a separate container combination of the present application;

FIGS. 9 to 10 are process diagrams of loading separate containers of the present application in a standard container;

FIG. 11 is a perspective structural diagram of an embodiment of a separate container of the present application (with the second side heat dissipation long edge shown);

FIG. 12 is a partial exploded structural view of an embodiment of a separate container of the present application;

FIG. 13 is a partial enlarged view of FIG. 12;

FIG. 14 is a partial exploded structural view of an embodiment of a separate container of the present application;

FIG. 15 is a perspective structural diagram of an embodiment of a first supporting frame of a separate container of the present application;

FIG. 16 is an M-direction view of FIG. 15;

FIG. 17 is a perspective structural diagram of an embodiment of a second supporting frame of a separate container of the present application;

FIG. 18 is an N-direction view of FIG. 14; and

FIG. 19 is a side view of an embodiment of a rack of a separately containerized server device of the present application.

### REFERENCE NUMERALS

1, 1′, 1a, 1b, 1c, 1d: Separate container
11: Corner post
12: Bottom side beam
13: Top side beam
14: Corner member
2, 2a, 2b, 2c, 2d: Standard container
100: Container body
110: First side heat dissipation long edge
120: Second side heat dissipation long edge
130: First side short edge
140: Second side short edge
200, 200a, 200b: Rack
210, 210a, 210b, 210c, 210d, 210e, 210f, 210g: Partition plate
230: Extension baffle
310: Power distribution cabinet
330a1, 330a2, 330b, 330c, 330d, 330e, 330f: Power distributor
400: Device row
500: Maintenance passage
600: Movable Wall
700: Closed wall
801: Protective Wall
802: Cable inlet
900: Cooling structure
910, 910a, 910b: Fan
920: Connecting framework
930: Supporting frame
931: First supporting frame
9311: First supporting fixing portion
9312: First limiting fixing portion
9313: First supporting portion
9314: First limiting portion
9315: First auxiliary supporting portion
932: Second supporting frame
9321: Second limiting fixing portion
9322: Second upper limiting portion
9323: Second lower limiting portion
9324: Second upper supporting portion
9325: Second lower supporting portion
9326: Second auxiliary supporting portion
940: Sealing framework
1000: Maintenance door

### DETAILED DESCRIPTION

The following describes the technical solutions of the present application in detail in conjunction with the drawings and specific embodiments so as to further understand the objectives, solutions and effects of the present application, but not to limit the scope of protection of the appended claims of the present application.

Currently, containerized servers have become a mainstream device in the computing device industry.

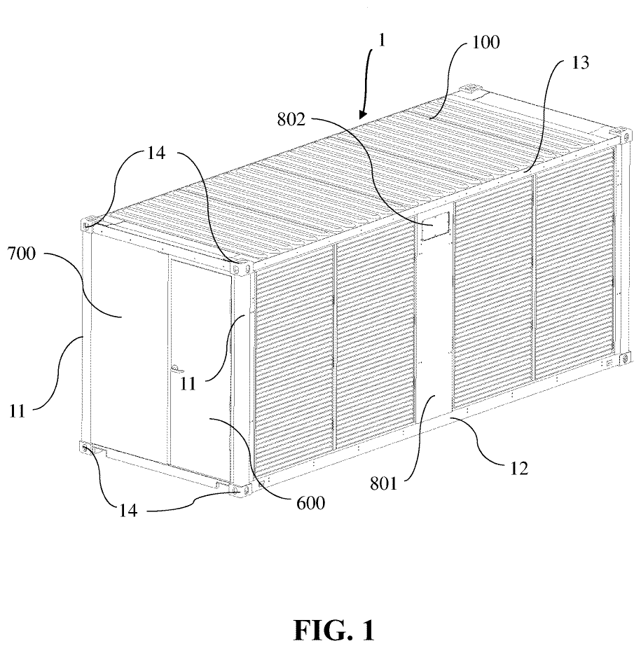

As shown in FIGS. 1 to 3, a separate container 1 of some embodiments of the present application includes a container body 100, a rack 200 and an electric control system, the rack 200 and the electric control system are respectively fixed in the container body 100, and the electric control system is used for connecting with servers carried by the rack 200. The electric control system includes a power distribution cabinet 310, and the rack 200 and the power distribution cabinet 310 are disposed in a row along a length direction of the container body 100 to form a device row 400.

The container body 100 is provided with a communication port in communication with another container body 100 disposed adjacently. By disposing the communication port, the adjacent separate containers can be in communication with each other. The communication port is located at an end along a length direction and/or height direction of the container body 100, and the communication port is provided with a movable wall 600. During transportation or when communication is not required, the communication port is closed by the movable wall 600; and when communication is required, the movable wall 600 may be removed or opened to make the adjacent separate containers 1 in communication.

The movable wall 600 includes a door and/or a detachable wall panel. In some embodiments of the present application, the communication port is at an entire end position of the container body 100 along the length direction, that is to say, an entire side face of the container body 100 along the length direction is the communication port, and the position of the entire side face is provided with an openable/closable door or a detachable wall panel which can achieve complete through-access.

In some embodiments of the present application, a maintenance passage 500 is formed between the device row 400 and a side wall of the container body 100, the movable wall 600 is disposed at a position of either side wall of the container body 100 along the width direction corresponding to the maintenance passage, and the container bodies 100 have connecting portions connected to each other along the length direction. When the doors are opened, the maintenance passages 500 of the adjacent separate containers 1 are in communication; and when the detachable wall panels are removed, the maintenance passages 500 of the adjacent separate containers 1 are in communication.

In some embodiments of the present application, the communication port is located at an end along the height direction of the container body 100, and the communication port is provided with a movable wall. That is to say, a position in a container top and/or container bottom of the container body 100 corresponding to an end of the maintenance passage 500 is provided with the movable wall for internal communication when the separate containers 1 are stacked up and down.

The separate containers 1 of some embodiments of the present application are a modular design, and each of the separate containers 1 may be used alone or superimposed and combined to achieve a more powerful computing capability. The plurality of separate containers 1 of some embodiments of the present application can be assembled along the length direction of the container bodies 100. When the opposite movable walls 600 of adjacent separate containers 1 are opened, the maintenance passages 500 of the separate containers 1 are in communication to form one communication passage.

For example, when computing power requirements are moderate, one separate container 1 may be employed to work independently. The movable walls 600 on two sides of the separate container 1 that are in communication with the maintenance passage 500 are, for example, openable/closable doors. When computing power requirements are relatively high, a form of two separate containers 2 working in a combination may be employed, or three or even more separate containers 2 may be employed to work in combination. Of course, some embodiments of the present application may also implement that the plurality of separate containers in different combination forms are employed to work together at the same location. Since each separate container 1 of some embodiments of the present application has the ability to work independently, no matter what combination form and number of combinations a user employs, it is feasible and no modification is required.

Preferably, a sealing structure is disposed in a slit between two separate containers 1 adjoining each other along the length direction of the container bodies 100, which avoids dust, rainwater, etc. from entering into the container bodies and affecting the performance of the device. The sealing structure is, for example, a rubber sealing strip, a foam sealing strip, a silicone sealing strip, a waterproof glue, and the like, which is simple to operate, low in cost, and highly adaptable.

In other embodiments, the separate containers 1 may be combined along the height direction of the container bodies 100. Alternatively, the separate containers 1 may be combined along the length direction and height direction of the container bodies 100 to form a matrix-type separately containerized server device. These are all within the scope of protection of the present application.

The separate container 1 of some embodiments of the present application employs the structural form of a standard container, as shown in FIG. 1. That is to say, the container body 100 of the separate container 1 of some embodiments of the present application is made of materials such as steel, aluminum alloy, etc., and has the characteristics of high strength, corrosion resistance, and wear resistance. The container body 100 of the separate container 1 of some embodiments of the present application is configured with a corner post 11, a bottom side beam 12, a top side beam 13, a corner member 14, etc. like the standard container, which are main structural components of the container and are used for supporting and reinforcing the container body 100 to make the same strong and rigid enough to withstand the weight of goods and the vibrations and impacts experienced in a transportation process.

The corner members 14 are mounted at 8 corners of the container body 100. A material used for the corner member 14 is high-strength steel, which has high load-bearing, no deformation, wear resistance, high temperature resistance and high strength and toughness. The corner member 14 is the outermost fitting among numerous fittings of the container, which is also the fitting that contacts other containers or the ground most frequently. Hence, from a certain perspective, it also assumes a role in protecting the container. The corner member 14 may serve as a fixing point to provide convenient fixation of the container body when goods are loaded and unloaded, as well as fixation and stability of the container in a transportation process.

The connecting portion includes a plurality of length connecting components located at an end along the length direction of the container body 100. The connecting portion includes a plurality of height connecting components located at an end along the height direction of the container body 100. The length connecting components are used for connection and fixation when adjacent separate containers 1 are assembled with each other along the length direction, and the height connecting components are used for connection and fixation when adjacent separate containers 1 are assembled with each other along the height direction.

The separate container 1 of some embodiments of the present application utilizes the characteristics of the corner member 14 to use it as the connecting portion during assembly of the separate container 1, and adjacent separate containers 1 are fixed through a connector.

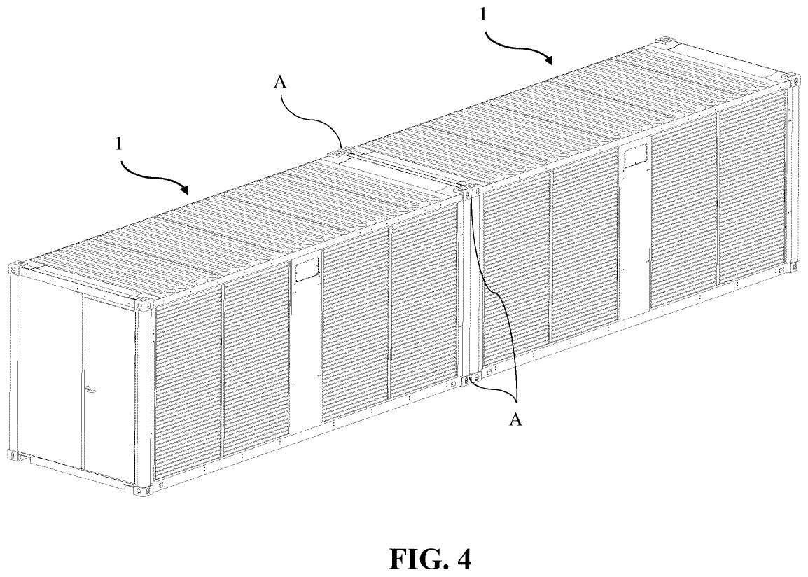

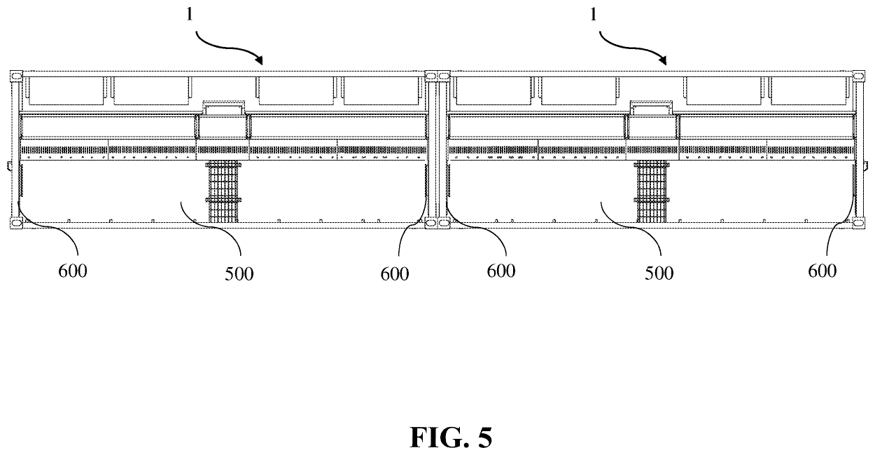

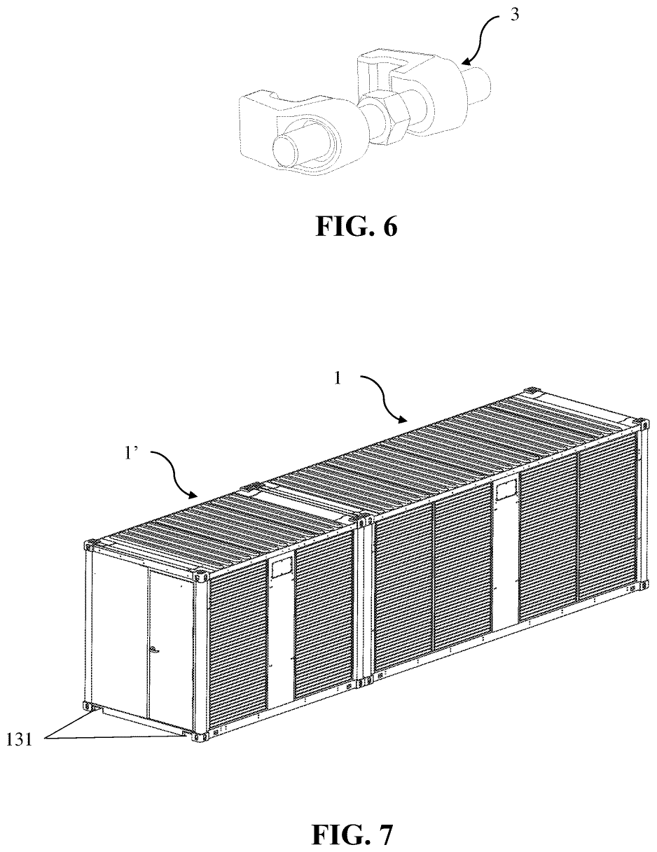

FIGS. 4 and 5 show a combination form of separate containers 1 of some embodiments of the present application, where two identical separate containers 1 are connected through a corner member connector 3 as shown in FIG. 6. With reference to FIGS. 1, 4, 5 and 6, two separate containers 1 are disposed adjacently along the length direction of the container bodies 100, the corner members 14 at mating side faces of the adjacent container bodies 100 are opposite, and at least one pair of opposite corner members 14 are connected through the corner member connector 3. It should be noted that there are many structural forms and connection modes of the corner member connector 3, which may be selected according to needs. Preferably, four corner members 14 at the mating side faces of the adjacent container bodies 100 are opposite one by one, as shown at A in FIG. 4, and four pairs of opposite corner members 14 are respectively connected to each other through the corner member connectors 3, making the structure firmer.

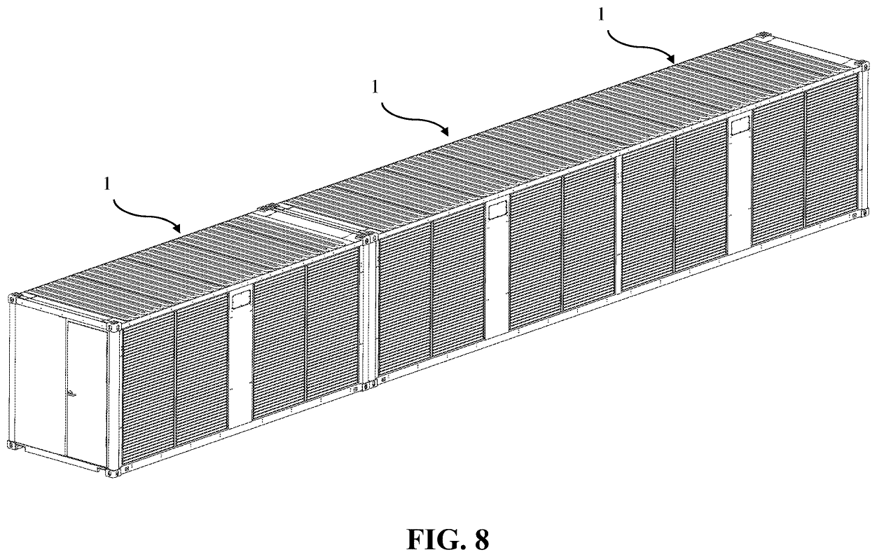

Some embodiments of the present application do not limit on the size and number of the separate containers 1 as combined together. In the embodiment shown in FIG. 7, two separate containers 1 and 1′ of different sizes are combined together, and in the embodiment shown in FIG. 8, three separate containers 1 with the same size are combined together.

In the embodiment shown in FIG. 7, along the length direction of the container bodies, bottoms of the container bodies are provided with bottom grooves. The bottom grooves are provided to implement two functions, one of which is to adjust the position of the containers during transportation and stacking by generally inserting a forklift into the bottom grooves and moving the container bodies left and right. The other function is that when the containers are piled, if there is some left-right misalignment between the two container bodies, the corner members will not hit end bottom beams (that is to say, the corner members can be stored after the misalignment and will not impact the bottom beams).

With reference to FIGS. 4 and 5, the movable wall 600 on the left side wall of the separate container 1 on the left corresponding to the maintenance passage 500 is an openable/closable door, and the movable wall 600 on the right side wall of the separate container 1 on the left corresponding to the maintenance passage 500 is a detachable wall panel. The movable wall 600 on the left side wall of the separate container 1 on the right corresponding to the maintenance passage 500 is a detachable wall panel, and the movable wall 600 on the right side wall of the separate container 1 on the right corresponding to the maintenance passage 500 is an openable/closable door.

After the left and right separate containers 1 are combined along the length direction of the container bodies 100 and connected through the corner member connectors 3, the detachable wall panel on the right side wall of the separate container 1 on the left and the detachable wall panel on the left side wall of the separate container 1 on the right may be removed, and then the maintenance passages 500 of the separate containers 1 on the left and right are in communication, and two ends of the communicating maintenance passages 500 have the openable/closable doors, respectively.

In other embodiments, two sides of the separate container 1 on the left or right may be provided with the openable/closable door, and after combination, the door at a part where communication is required may be opened. The door is, for example, a sliding door, which occupies less space.

When the separate containers 1 are combined along the height direction of the container bodies 100, the corner members 14 may likewise be employed as the connecting portions of the separate containers 1, and the opposite corner members 14 of the vertically adjacent separate containers 1 are fixed to each other through the corner member connectors 3. When the separate containers 1 are combined along the length direction and height direction of the container bodies 100, the opposite corner members 14 of the laterally and vertically adjacent separate containers 1 are fixed to each other through the corner member connectors 3 to form a combined integral device.

When the separate containers 1 are combined along the height direction of the container bodies 100, opposite positions where a bottom plate of an upper container body or a top plate of a lower container body are mated at the maintenance passages 500 of the separate containers 1 are provided with openings to make an internal space between the adjoining separate containers 1 in communication, facilitating overall monitoring and maintenance and service of the staff. A ladder, for example, is provided at the openings for access to upper and lower spaces. The ladder is preferably a foldable ladder, which may be unfolded when needed to be used and retracted when not needed, without occupying the space of the maintenance passage 500.

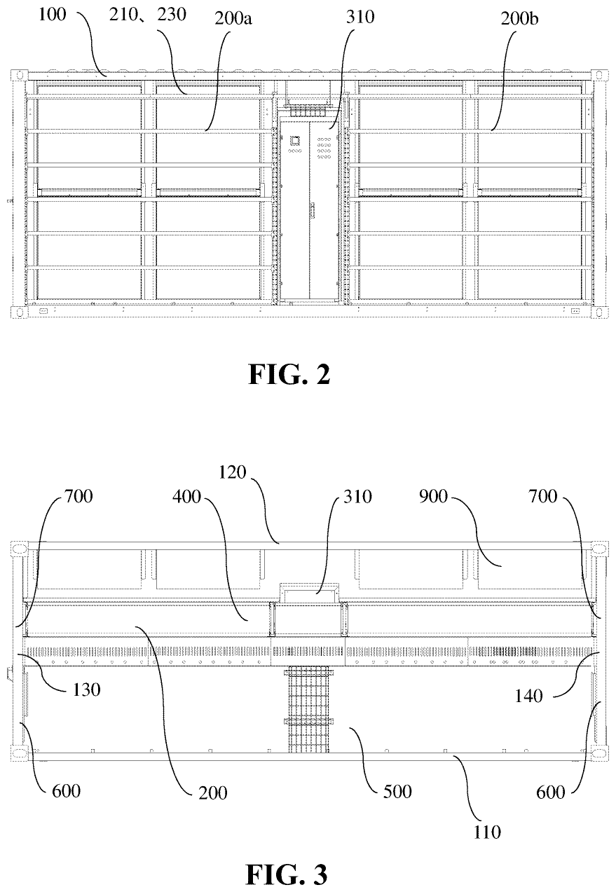

In some embodiments of the present application, as shown in FIGS. 2 and 3, the rack 200 and the power distribution cabinet 310 are disposed in a row along the length direction of the container body 100 to form a device row 400, making full use of a space inside the container body 100. Preferably, in some embodiments of the present application, the racks 200 are configured symmetrically on the two sides of the power distribution cabinet 310.

By providing a symmetrical configuration of the racks 200 on the two sides of the power distribution cabinet 310, the same number of servers with the same specifications can be arranged on the racks 200, so that power lines leading out of the power distribution cabinet 310 to two ends are evenly distributed and clearly routed, which makes it easy for staff to manage and maintain and can avoid troubles caused by too many and too long power lines and complex wiring redundancy due to single-side cabling, thereby reducing maintenance manpower and device costs. Moreover, this can further ensure the overall counterweight balance of the container and increase the overall reliability of the device.

In this embodiment, as shown in FIG. 2, one rack 200a and one rack 200b are separately configured on the two sides of the power distribution cabinet 310. The racks 200a and 200b have the same specifications, or in other words, the racks 200a and 200b have the same length, width, and height so as to have the ability to carry the same number of servers with the same specifications.

It should be noted that the “one” rack here does not refer to one in the physical sense, but means that the racks on the two sides of the power distribution cabinet have the same specifications and the same ability to carry servers, so that the power distribution cabinet evenly supplies power to the two sides. The racks on the two sides of the power distribution cabinet may also be connected to each other to form an integrated whole.

In other embodiments, the two sides of the power distribution cabinet 310 may be symmetrically configured with two or more racks 200 having the same number and specifications, so as to ensure that the power distribution cabinet 310 evenly routes lines and transmits power to servers on the racks in directions of the two sides, and enable balance in both power line distribution and weight distribution.

The above electric control system not only has power distribution function, but also includes air conditioning function, cabinet power management function, remote monitoring function and the like, which ensure the normal operation and management of the server container through collaboration among various components. The air conditioning function part includes an air conditioning controller, a compressor, a fan and other components, which are used for maintaining a temperature and humidity inside the server container; the cabinet power management function part is used for monitoring and managing a power supply of each cabinet, including powering on and off, restarting, monitoring power consumption, etc.; the remote monitoring function part is used for remotely monitoring a status of the server container, including collecting and analyzing information such as temperature, humidity, power consumption, and network connection. Some embodiments of the present application further have circuit breaker cascade protection, full power distribution monitoring and remote transmission functions.

With reference to FIG. 3, the container body 100 of the separate container 1 of some embodiments of the present application includes a first side heat dissipation long edge 110, a second side heat dissipation long edge 120, a first side short edge 130, and a second side short edge 140, wherein the first side heat dissipation long edge 110 and the second side heat dissipation long edge 120 are symmetrically disposed along the length direction of the container body 100, and the first side short edge 130 and the second side short edge 140 are symmetrically disposed along the width direction of the container body 100.

The device row 400 formed by disposing the rack 200 and the power distribution cabinet 310 in a row is disposed along a direction in which the first side heat dissipation long edge 110 and the second side heat dissipation long edge 120 extend, and two sides of the device row 400 separately abut against the first side short edge 130 and the second side short edge 140.

The maintenance passage 500 is formed between the device row 400 and the first side heat dissipation long edge 110. The maintenance passage 500 is used for the staff to conduct regular inspection, maintenance and upkeep for systems, devices, networks, and the like to ensure that they can normally operate, prevent failures and accidents, and improve the reliability and stability of the systems. The regular maintenance and upkeep can extend the service life of the systems, devices, networks, and the like, reduce the frequency and cost of replacement and repair, and optimize the systems, devices, networks, and the like, thereby improving system performance and efficiency and reducing resource wastes. Meanwhile, the maintenance passage can also be used to perform security inspection and protection on the systems, devices, networks, and the like to ensure the security and confidentiality of information.

The maintenance passage 500 of some embodiments of the present application is spacious and smooth. After a plurality of separate containers 1 are combined, the maintenance passages 500 of the separate containers 1 are in communication, and the staff may enter the maintenance passages 500 from a side thereof, inspect, maintain and service the systems, devices and networks in the container bodies 100, and then walk out from the other side, which is convenient and quick and can effectively improve the working efficiency.

In an embodiment of the separate container 1 of some embodiments of the present application, positions of two side walls of the container body 100 along the width direction not corresponding to the maintenance passage 500 are provided as fixed side walls. That is to say, positions of the first side short edge 130 and the second side short edge 140 corresponding to the rack 200 and between the rack 200 and the second side heat dissipation long edge 120 are provided as closed walls 700. At positions of the first side short edge 130 and the second side short edge 140 only corresponding to the maintenance passage 500 are openable/closable doors or detachable wall panels, while where the first side short edge 130 and the second side short edge 140 do not correspond to the maintenance passage 500, there are the closed walls sealed to top, which simplifies unnecessary design, and reduces safety hazards and the costs of maintenance and device manufacturing.

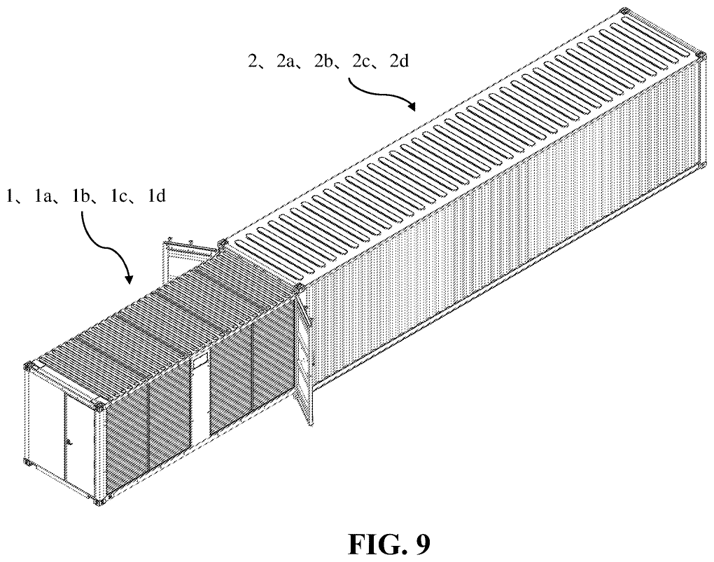

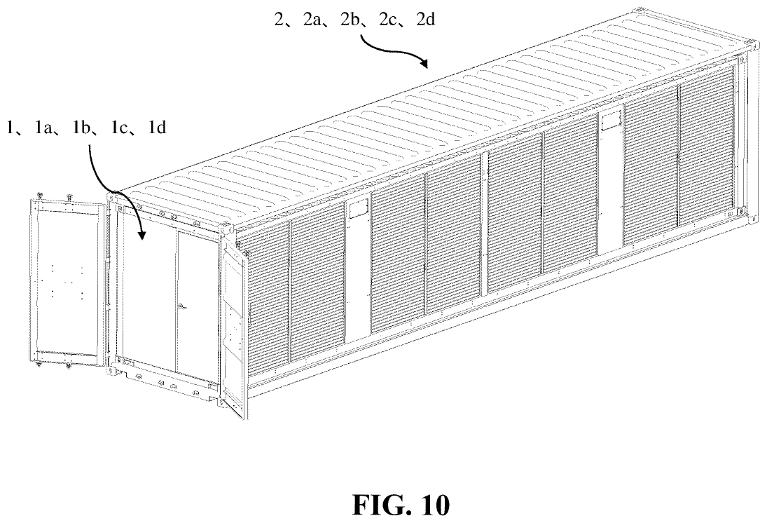

In an embodiment of the separate container 1 of some embodiments of the present application, as shown in FIGS. 9 and 10, an external size of length, width and height of the container body 100 is smaller than a size of an internal space of a standard container 2, and the container body 100 can be integrally loaded in the standard container 2.

The server container employs the structural form of a container, and the structural design of the container makes it standardized, universal, and efficient, which facilitates transportation, loading and unloading of goods. However, if it is directly used for transportation, loading and unloading as a standard container, varying degrees of damage may be caused to the goods and the container itself in a case where the container is collided or shaken in a process of transporting the container for a long distance, including land and sea transportation. Specific consequences include damage to the container itself. Due to collision, shaking and other reasons, the container body, door, sealing means and other components of the container may suffer damage, such as deformation, breakage, loose sealing, etc. It is also very possible to endanger the goods in the container. Due to collision, shaking and other reasons, the goods in the container may suffer damage, such as breakage and deformation.

In terms of the separate container 1 of some embodiments of the present application, if the separate container 1 is directly transported as a standard container for a long distance, for example, in sea or land transportation, the separate container 1 is very susceptible to damage in a transportation process. In a least serious situation, an exterior of the container body 100 may suffer damage, including deformation, breakage, etc., and damage caused to an air-cooling structure, an accessory connection structure or the like on the periphery of the container body 100 will directly affect structures of the servers for heat dissipation, sealing and the like, causing the servers and network devices to be unable to work normally for a long time. In a most serious situation, the rack 200, the electric control system or the like in the container body 100 may be damaged, causing the entire system unusable, and resulting in huge losses.

An external size of length, width and height of the container body 100 designed in some embodiments of the present application is smaller than a size of an internal space of a standard container 2, so that the separate container 1 of some embodiments of the present application can be integrally loaded in the standard container 2.

The size of the standard container is usually specified according to the ISO 668 standard, covering different sizes such as 10-foot , 20-foot, 40-foot, 45-foot, etc. The 10-foot (about 2991 mm long, about 2438 mm wide, about 2591 mm high), 20-foot (about 6058 mm long, about 2438 mm wide, and about 2438 mm high), 40-foot (about 12192 mm long, about 2438 mm wide, and about 2438 mm high), and 40-foot high cube (about 12192 mm long, about 2438 mm wide, and about 2896 mm high) side-opening standard containers are mainstream forms widely used in the logistics and transportation field and have many complete loading and unloading measures. Standardized container sizes make it convenient to load, unload and transport goods, and also improve the efficiency and safety of transportation of the goods.

The separate container 1 of some embodiments of the present application is preferably used with the 10-foot, 20-foot and 40-foot side-opening standard containers 2.

For example, when used with a 10-foot standard container 2a, a size of an internal space of the 10-foot standard container 2a is about 2831 mm (length)×2352 mm (width)×2385 mm (height), a separate container 1a has a container body 100 with an external size of length, width, and height slightly smaller than the size of the internal space of the 10-foot standard container 2a. That is to say, one separate container la is loaded in and transported with one 10-foot standard container 2a.

When used with a 20-foot standard container 2b, a size of an internal space of the 20-foot standard container 2b is about 5898 mm (length)×2352 mm (width)×2393 mm (height), a separate container 1b has a container body 100 with an external size of length, width, and height slightly smaller than the size of the internal space of the 20-foot standard container 2b. That is to say, one separate container 1b is loaded in and transported with one 20-foot standard container 2b. Also, two of the above separate containers la intended to be loaded in the 10-foot standard containers 2a may be loaded in one 20-foot standard container 2b by sequentially loading the two separate containers la therein along a length direction of the 20-foot standard container 2b.

When used with a 40-foot standard container 2c, a size of an internal space of the 40-foot standard container 2c is about 12032 mm (length)×2352 mm (width)×2393 mm (height), a separate container 1c has a container body 100 with an external size of length, width, and height slightly smaller than the size of the internal space of the 40-foot standard container 2c. That is to say, one separate container 1c is loaded in and transported with one 40-foot standard container 2c. Of course, two of the above separate containers 1b intended to be loaded in the 20-foot standard containers 2b may also be loaded in one 40-foot standard container 2c by sequentially loading the two separate containers 1b therein along a length direction of the 40-foot standard container 2c. Alternatively, two separate containers la and one separate container 1b are loaded in the 40-foot standard container 2c by sequentially loading the two separate containers 1a and the one separate container 1b therein along the length direction of the 40-foot standard container 2c. Alternatively, four separate containers la are loaded in the 40-Attorney foot standard container 2c by sequentially loading the four separate containers la therein along the length direction of the 40-foot standard container 2c.

When used with a 40-foot high cube standard container 2d, a size of an internal space of the 40-foot high cube standard container 2d is about 12032 mm (length)×2352 mm (width)×2698 mm (height), a separate container 1d has a container body 100 with an external size of length, width, and height slightly smaller than the size of the internal space of the 40-foot high cube standard container 2d. Similarly, the 40-foot high cube standard container 2d may also be loaded with a plurality of separate containers 1 of the same size or different sizes.

In terms of practical applications, the 40-foot high cube one, due to its higher height, can carry a higher separate container 1 and have higher and better integration performance.

It should be noted that the above are merely examples, and the separate containers of some embodiments of the present application may be used with standard containers of any size, which are all within the scope of protection of the present application.

The length of the size of the internal space inside the container is a distance measured between a container door inner side plate and an end wall inner lining plate, the width is a distance between two inner side lining plates, and the height is a distance from a container bottom plate face to a lowermost container top plate face. The size may vary slightly due to differences among shipping companies.

When the container body 100 of the separate container 1 of some embodiments of the present application is loaded in the standard container 2, first to fourth gaps are present between four side walls of the container body 100 and four side inner walls of the standard container 2, and a fifth gap is present between a top wall of the container body 100 and a top inner wall of the standard container 2.

In detail, the first gap and second gap are respectively present between left and right side walls of the container body 100 along a length direction and left and right inner walls of the standard container 2 along the length direction. The third gap and fourth gap are respectively present between front and rear side walls of the container body 100 along a width direction and front and rear inner walls of the standard container 2 along the width direction. The fifth gap is present between the top wall of the container body 100 and the top inner wall of the standard container 2.

In general, a sum of the first gap and the second gap is 90±20 mm, a sum of the third gap and the fourth gap is 90±20 mm, and the fifth gap is 40±10 mm.

The gaps may be distances between four wall faces and a top wall face of the container body 100 and four sides and the top inner wall of the standard container 2. In some embodiments, each corner member 14 of the container body 100 protrudes relative to a wall face, and each gap may also be a distance between a side contour face or top contour face of each corner member 14 of the container body 100 and the four sides and top inner wall of the standard container 2.

The first to fifth gaps are used for providing a relative moving distance for the separate container 1 to move when loaded in the standard container 2, and providing an assembly margin for manufacturing error, movement shaking, and minor deformation, so as to prevent the separate container 1 from being unable to enter the standard container 2, or from being stuck and unable to move relatively in a loading process.

When being loaded, the separate container 1 is pushed into the standard container 2 by a forklift or a hydraulic push rod; and when being unloaded, the separate container 1 is pulled out of the standard container 2 by connecting the corner member 14 of the container body 100 of the separate container 1 through a connector (e.g., a rope, a steel wire, etc.).

Preferably, the separate container 1 is assisted in pushing in or pulling out of the standard container 2 by mounting rolling or sliding members at the bottom, which reduces friction between the separate container 1 and the standard container 2 in loading and unloading processes, thereby reducing vibration and wear. A movement assisting accessory is, for example, a roller connected to the bottom of the container body 100 of the separate container 1, or a slide rail means connected between the bottom of the container body 100 and a bottom plate of the standard container 2.

In detail, the movement assisting accessory includes a roller means connected to the bottom of the container body 100. The roller means is connected to a bottom of the corner member 14 of the container body 100, or the roller means is connected to the bottom side beam 12 and/or the bottom of the corner member 14 of the container body 100. The roller means is, for example, a metal wheel mounted at the bottom of the container so that the container can move on the ground. The container wheel may be fixed or rotated, so as to facilitate adjustment to a direction of the container.

The movement assisting accessory includes a slide rail means connected to the bottom of the container body 100 or to a bottom plate of the standard container 2. The slide rail means is generally metal and allows the container to slide along the slide rail, which can withstand the weight and friction of the container and facilitate movement of the container.

The movement assisting accessory includes a slide plate means connected to the bottom of the container body 100 or to the bottom plate of the standard container 2. The slide plate is mounted between the bottom plate of the standard container and the bottom of the separate container. The slide plate means is made of, for example, a metal plate and allows for relative sliding between the separate container and the standard container, reducing friction when the container moves.

After the separate container 1 is pushed into the standard container 2, the corner member 14 of the container body 100 of the separate container 1 is connected with a rope ring disposed at a respective corner in the standard container 2. After the separate container 1 is pushed into the standard container 2, a buffer member is placed in at least one of the first to fifth gaps, which can further prevent shaking and collision.

The buffer member includes a wooden structural member, a corner protection structural member, an edge structural member, a foam member, etc. The wooden structural member is disposed at a bottom of at least one of the first to fifth gaps. The operation is convenient and the buffering effect is good. The corner protection structural member is mounted on the corner member 14 of the container body 100. The corner protection structural member is, for example, a wooden material member, a plastic material member, a foam material member or a rubber material member. The corner protection structural member buffers the corner member 14 of the container body 100, reduces a force when the corner member 14 collides with inside of the standard container 2, and protects the container body 100. The edge structural member is mounted to at least one of the corner post 11, the bottom side beam 12, and the top side beam 13 of the container body 100. The edge structural member is, for example, in an L-shape, and is a wooden material member, a plastic material member, a foam material member or a rubber material member. The edge structural member buffers the side beams and the corner posts of the container body 100, reduces a force when the side beams and the corner posts collide with the inside of the standard container 2, and protects the safety of the container body. The foam member is filled in at least one of the first to fifth gaps. The foam member is used for forming a buffer between wall faces of the container body 100 and the standard container 2.

The above buffer members may be used in combination to separately provide buffering protection or multiple protection to different parts of the container body 100.

When the plurality of separate containers 1 are loaded in one standard container 2, the plurality of separate containers 1 are sequentially loaded therein along the length direction of the standard container 2.

As shown in FIG. 1, FIG. 3 and FIGS. 11-13, the first side heat dissipation long edge 110 of the container body 100 is provided with an air inlet structure, and the second side heat dissipation long edge 120 is provided with a cooling structure 900. The first side heat dissipation long edge 110 and the second side heat dissipation long edge 120 disposed oppositely form an air flow to dissipate heat from and cool the servers in the container body 100. Some embodiments of the present application achieve a simple structure, low costs, and good heat dissipation effect by oppositely disposing the first side heat dissipation long edge 110 and the second side heat dissipation long edge 120.

A three-layer protective structure (of filter, shutter and water curtain) on the air inlet side employs a large-volume direct-driven negative pressure fan and cold and hot zone isolation. It has an intelligent management platform and a double-layer heat insulation design on the top.

In an embodiment, a shutter structure is provided on the first side heat dissipation long edge 110, and the cooling structure 900 is provided on the second side heat dissipation long edge 120; alternatively, a dustproof mesh structure is provided on the first side heat dissipation long edge 110, and the cooling structure 900 is provided on the second side heat dissipation long edge 120, wherein the dustproof mesh structure is, for example, a metal cut mesh or a metal woven mesh with mesh holes; alternatively, shutter and dustproof mesh structures are provided on the first side heat dissipation long edge 110, and the cooling structure 900 is provided on the second side heat dissipation long edge 120, each having good impurity prevention and wind cooling effects

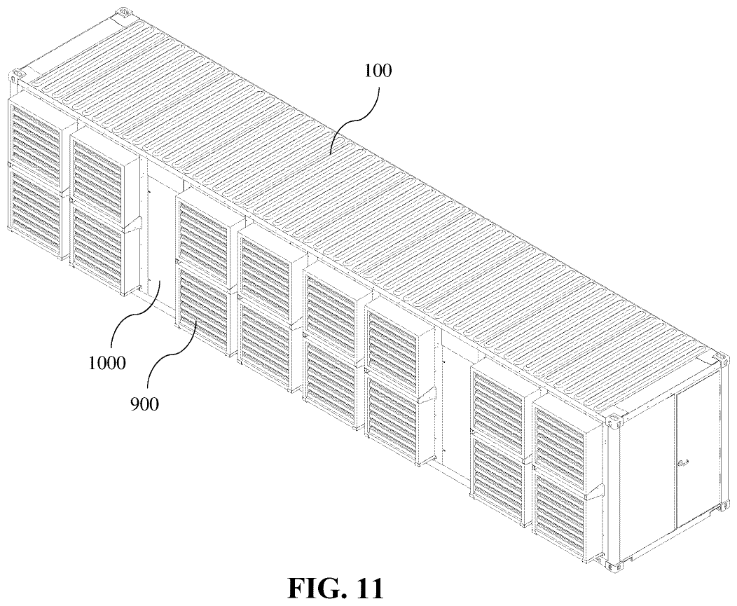

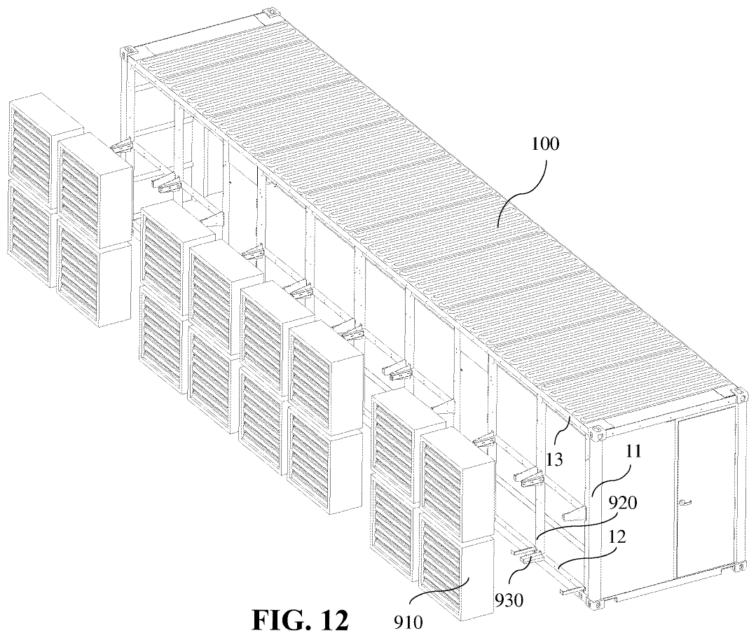

As shown in FIGS. 11 and 12, the cooling structure 900 includes a plurality of fans 910. By introducing external air into the inside of the container and allowing the air to flow through the fans 910, the heat will be removed, so as to keep a temperature inside the container from being too high.

The cooling structure 900 further includes a connecting framework 920 and a supporting frame 930. The connecting framework 920 is connected to the bottom side beam 12 and the top side beam 13 of the container body 100. Alternatively, in some embodiments, the connecting framework 920 is connected to the bottom side beam 12, the top side beam 13 and the corner post 11 of the container body 100, making the structure stable.

The supporting frames 930 are detachably connected to the connecting framework 920 through a plurality of fasteners, and the fans 910 are disposed on the supporting frames 930. Furthermore, the fans 910 are connected with the power distribution cabinet 310 of the electric control system. When mounting, only a main incoming cable needs to be connected to the power distribution cabinet 310, and no other mounting work is required.

In detail, the cooling structure 900 is connected between the bottom side beam 12, the top side beam 13 and the corner post 11 of the second side heat dissipation long edge 120 of the container body 100. When the separate container 1 of some embodiments of the present application is transported over a long distance, the supporting frames 930 are connected to an inner side of the connecting framework 920 located inside the container body 100, and the fans 910 are located on the supporting frames 930. That is to say, the fans 910 are located in a space between the second side heat dissipation long edge 120 and the device row 400, and will not protrude outside the container body 100. When the separate container 1 of some embodiments of the present application is in use, the fans 910 may be in a state during transportation. That is to say, the fans 910 are still working while being built into the container body 100. The supporting frames 930 are detachably connected to the inner side of the connecting framework 920 located inside the container body 100. Meanwhile, an outer side of the connecting framework 920 located outside the container body 100 likewise has supporting frame connecting portions. The supporting frames 930 may be connected to the supporting frame connecting portions of the connecting framework 920 located on the outer side of the container body 100, achieving outer placement of the fans 910.

In an embodiment of the present application, there are a plurality of groups of connecting frameworks 920, for example, wherein at least one group of connecting frameworks 920 is partially connected to a front corner post of the container body 100 located on the front side, and at least one group of connecting frameworks 920 is partially connected to a rear corner post of the container body 100 located on the rear side. Of course, in some embodiments, there may also be a group of connecting frameworks 920.

In the embodiments shown in FIGS. 11 and 12, there are four groups of connecting frameworks 920, each carrying 4 fans through the supporting frames 930, with the 4 fans arranged in a grid pattern of four squares. However, some embodiments of the present application do not limit the number of the fans 910 in the cooling structure 900, and the fans may be arranged according to their size, shape, and exhaust volume as long as the heat dissipation requirements are met.

The supporting frame 930 is formed by bending and machining a metal plate, for example. Specifically, the supporting frame 930 is machined to form a fixing portion for detachably connecting to the inner side or outer side of the connecting framework 920 through a fastener, a supporting portion for supporting the fan, and a limiting portion for limiting the fan 910 on the supporting portion to avoid the fan 910 from moving or shaking.

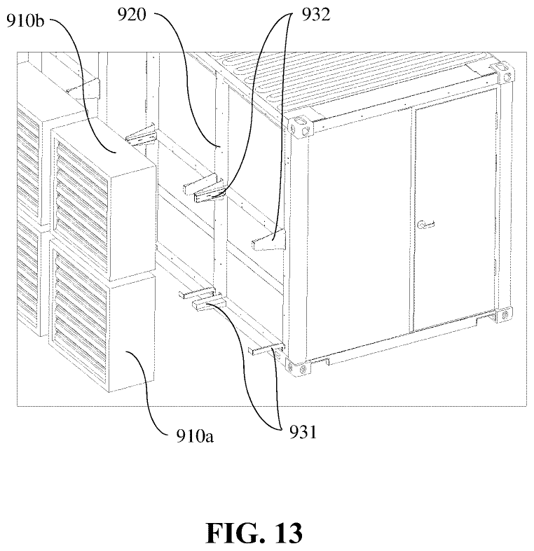

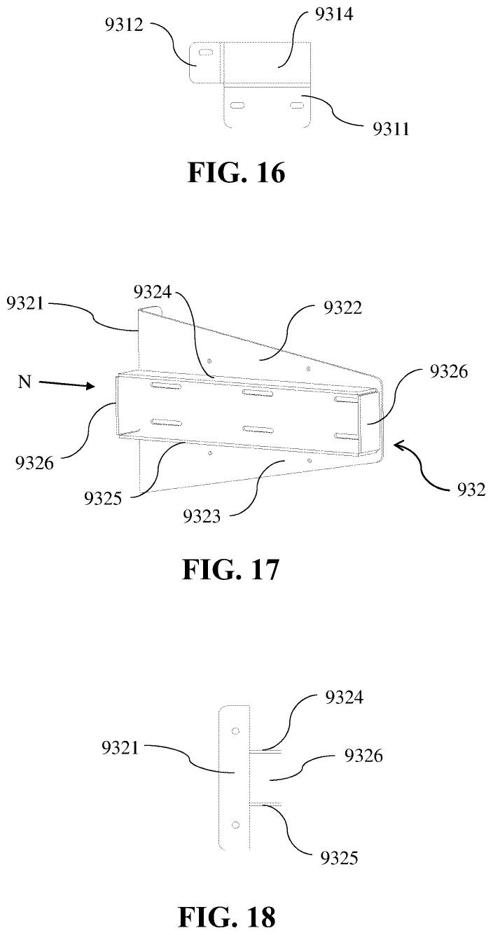

With reference to FIGS. 13, 15, and 16, the supporting frame 930 includes a first supporting frame 931 including a first supporting fixing portion 9311, a first limiting fixing portion 9312, a first supporting portion 9313, and a first limiting portion 9314. The first supporting fixing portion 9311 is connected with the first supporting portion 9313, and the first limiting fixing portion 9312 is connected with the first limiting portion 9314. Taking a horizontal supporting surface of the first supporting portion 9313 as a reference, the first supporting fixing portion 9311 is formed, for example, by bending a metal plate integral with the first supporting portion 9313 downward by ninety degrees, the first limiting portion 9314 is formed, for example, by bending the metal plate integral with the first supporting portion 9313 upward by ninety degrees, and the first limiting fixing portion 9312 is formed, for example, by bending the metal plate integral with the first limiting portion 9314 by ninety degrees in a direction away from the first supporting portion 9313. Preferably, the first supporting fixing portion 9311 and the first limiting fixing portion 9312 are in the same plane. As shown in FIG. 15, the first supporting fixing portion 9311 is connected to a short edge side of the first supporting portion 9313, and there are two first limiting portions 9314 connected to two adjacent sides (a long edge side and a short edge side) of the first supporting portion 9313 that are different from the side connected to the first supporting fixing portion 9311, the two first limiting portions 9314 constituting a limiting angle. The other short edge side of the first supporting fixing portion 9311 is further bent downward to form a first auxiliary supporting portion 9315. The first auxiliary supporting portion 9315 functions as a reinforcing rib, which can enhance the supporting strength of the first supporting fixing portion 9311.

The first supporting fixing portion 9311 and the first limiting fixing portion 9312 are separately provided with a connecting hole, and the fasteners are connected with the inner side or the outer side of the connecting framework 920 through the connecting holes on the first supporting fixing portion 9311 and the first limiting fixing portion 9312.

With reference to FIG. 13, a first supporting frames 931 is disposed corresponding to a corner of a fan 910a, and two first supporting frames 931 are disposed oppositely and correspond separately to two corners at a bottom of the fan 910a. The other two corners at the bottom of the fan 910a may be supported on the connecting framework 920. That is to say, the two corners at the bottom of the fan 910a that are farther from the second side heat dissipation long edge 120 are separately limited by limiting angles of the first supporting frames 931 constituted by the first limiting portions 9314, and the two corners at the bottom of the fan 910a that are closer to the second side heat dissipation long edge 120 are supported by the connecting framework 920.

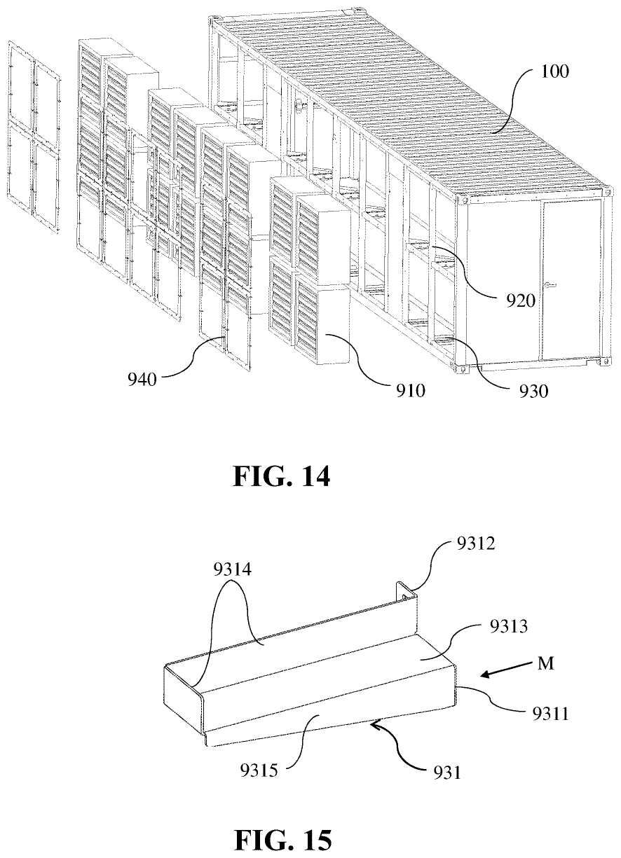

Meanwhile, as shown in FIG. 14, the cooling structure 900 further includes a sealing framework 940 which is, for example, an integrally formed metal member. The fans 910 are limited and sealed from the outer side of the container body 100 through the sealing framework 940.

Preferably, four corners of the fan 910 are supported and limited by the first supporting frames 931. Four first supporting frames 931 are oppositely connected to the connecting framework 920 corresponding to the four corners of the fan 910.

It should be noted that the above connecting framework 920 is, for example, in the shape of a square, but when the fans 910 are arranged in the grid pattern of four squares, the connecting framework 920 is, for example, in a grid pattern of four squares, and the fans 910 are connected in each square of the connecting framework 920.

In some embodiments, the connecting framework 920 is, for example, in the shape of a long rod, but when the fans 910 are arranged in the grid pattern of four squares, the connecting framework 920 is, for example, in the shape of a cross, and the cross-shaped connecting framework 920, along with the top side beam 13, the bottom side beam 12 and the corner post 11 of the container body 100, constitutes a framework for connecting the first supporting frames 931. For example, first supporting frames 931 corresponding to bottom corners of a fan 910 may be connected to the corner post 11 and/or the bottom side beam 12, and first supporting frames 931 corresponding to top corners of the fan 910 may be connected to the corner post 11 and/or the top side beam 13. At this point, the other two corners at the bottom of the fan 910 may be supported on the bottom side beam 12.

The sealing framework 940 is disposed along four sides of the fan 910. There is a sealant or a sealing tape between the sealing framework 940 and the connecting framework 920.

As shown in FIGS. 12, 17, and 18, the supporting frame 930 further includes a second supporting frame 932 connected between the fans 910a and 910b disposed in upper and lower positions for supporting and limiting upper corners of the lower fan 910a and bottom corners of the upper fan 910b. That is to say, the second supporting frame 932 can complete the functions of two first supporting frames 931 disposed adjacent to each other in upper and lower positions. When the fans 910 are disposed in upper and lower positions, the second supporting frame 932 may be employed to replace two first supporting frames 931 disposed adjacent to each other in upper and lower positions, which can reduce an area occupied by the supporting frames, increase an area for the fans, and thereby improve the air volume.

As shown, the second supporting frame 932 includes a second limiting fixing portion 9321, a second upper limiting portion 9322, a second lower limiting portion 9323, a second upper supporting portion 9324, and a second lower supporting portion 9325. The second upper limiting portion 9322 and the second lower limiting portion 9323 are disposed in upper and lower positions, the second limiting fixing portion 9321 is connected to vertical side edges of the second upper limiting portion 9322 and the second lower limiting portion 9323, and the second upper supporting portion 9324 and the second lower supporting portion 9325 are transversely connected between the second upper limiting portion 9322 and the second lower limiting portion 9323.

The second upper limiting portion 9322 and the second lower limiting portion 9323 are an integral metal plate as vertically disposed. Taking limiting faces of the second upper limiting portion 9322 and the second lower limiting portion 9323 facing the fans 910 as a reference, the second limiting fixing portion 9321 is formed, for example, by bending a metal plate integral with the second upper limiting portion 9322 and the second lower limiting portion 9323 in a direction away from the fans 910. The second upper supporting portion 9324 and the second lower supporting portion 9325 are connected to surfaces where the limiting faces of the second upper limiting portion 9322 and the second lower limiting portion 9323 are located, and are disposed in upper and lower positions. The second upper supporting portion 9324 is formed, for example, by bending an upper side edge of the vertically disposed metal plate connected between the second upper limiting portion 9322 and the second lower limiting portion 9323 downward by ninety degrees toward a direction where the fans 910 are located, and the second lower supporting portion 9325 is formed, for example, by bending a lower side edge of the vertically disposed metal plate connected between the second upper limiting portion 9322 and the second lower limiting portion 9323 upward by ninety degrees toward the direction where the fans 910 are located.

Further, the second supporting frame 932 further includes a second auxiliary supporting portion 9326 connected between the second upper supporting portion 9324 and the second lower supporting portion 9325 which are disposed in parallel in upper and lower positions. There are two second auxiliary supporting portion 9326 as disposed oppositely, which, for example, are formed by bending left and right side edges of the vertically disposed metal plate where the second upper supporting portion 9324 and the second lower supporting portion 9325 are located by ninety degrees toward the second upper supporting portion 9324 and the second lower supporting portion 9325. The second auxiliary supporting portions 9326 function to provide reinforcement support and can enhance the supporting strength of the second upper supporting portion 9324 and the second lower supporting portion 9325.

The second limiting fixing portion 9321 is provided with a connecting hole, and a fastener is connected with the inner side or the outer side of the connecting framework 920 through the connecting hole on the second limiting fixing portion 9321.

In some embodiments of the present application, when a plurality of fans 910 are arranged and disposed in upper and lower positions, the first supporting frame 931 may correspond to bottom corners of a lower fan 910, or the first supporting frame 931 may correspond to the bottom corners of the lower fan 910 and top corners of an upper fan 910, and the upper and lower fans 910 are supported and limited by the second supporting frame 932. The second upper limiting portion 9322 and the second upper supporting portion 9324 of the second supporting frame 932 separately correspond to bottom corners of the upper fan 910, and the second lower limiting portion 9323 and the second lower supporting portion 9325 of the second supporting frame 932 separately correspond to top corners of the lower fan 910.

When the fans 910 are disposed on three or even more layers, the first supporting frame 931 and the second supporting frame 932 are used in the same manner as above. The first supporting frame 931 is disposed corresponding to bottom corners of a fan on a bottom layer and top corners of a fan on a top layer, and the second supporting frame 932 is disposed corresponding to the other opposite corners of the fans except the bottom corners and the top corners for simultaneously supporting and limiting the corresponding corners of the two upper and lower fans.

It should be noted that only the first supporting frame 931 may be employed in a case where a side face space of the container body 100 allows, or the air volume of the fans 910 is sufficient for use. Of course, in some embodiments, only the second supporting frame 932 may be employed.

The first supporting portion 9313 of the first supporting frame 931 and the supporting surface of the connecting framework 920 that supports the fan 910 are substantially in the same plane. When the fan 910 needs to be placed outside, the sealing framework 940 on the outer side of the container body 100 is removed, the first supporting frame 931 and/or the second supporting frame 932 are connected to the connecting framework 920 on the outer side of the container body 100, and the fan 910 may be pulled to the outer side of the container body 100 along a plane constituted by the first supporting portion 9313 of the first supporting frame 931, the second upper supporting portion 9324 and second lower supporting portion 9325 of the second supporting frame 932, and the connecting framework 920. In a pulling process, the first limiting portion 9314 of the first supporting frame 931 and the second upper limiting portion 9322 and second lower limiting portion 9323 of the second supporting frame 932 constitute a movement limit on the fan 910.

When the separate container 1 of some embodiments of the present application is loaded and transported, the supporting frame 930 of the cooling structure 900 is connected to the connecting framework 920 inside the container body 100 through fasteners. In actual use, the fans 910 may be external or built-in to meet the requirements of different geographical conditions and heat dissipation conditions.

A plurality of prefabricated connection holes are disposed on the container body 100 of some embodiments of the present application, which are precisely positioned with various accessories, eliminating the need for on-site drilling and mounting, and facilitating multiple disassembly and mounting of accessories, thereby extending the service life. The prefabricated connection holes, for example, employ blind rivet holes, which have good sealing properties.

As shown in FIGS. 3 and 11, along the second side heat dissipation long edge 120, the cooling structure 900 is disposed at a position corresponding to the rack 200, and a position corresponding to the power distribution cabinet 310 is provided with a maintenance door 1000, through which the staff can conduct professional work, such as cleaning, inspection, maintenance, replacement, and upgrading, on the power distribution cabinet 310.

Since the power distribution cabinet 310 is in a high temperature and high humidity working environment, regular maintenance is required to ensure its safe and reliable operation. When maintenance is required, the staff walk to outside of the second long side edge 120 of the container body 100, open the maintenance door 1000 facing the power distribution cabinet 310 between the cooling structure 900, and then may directly enter into the container body 100 to conduct professional work on the power distribution cabinet 310.

It should be noted that maintenance of the power distribution cabinet 310 needs to follow relevant safety standards and operating procedures to avoid safety accidents. During maintenance and repairs, it is necessary to use professional tools and devices, and follow the relevant operating procedures and safety standards.

Based on this, a door lock is disposed on the maintenance door 1000 in some embodiments of the present application, which usually supports a plurality of door opening manners, such as password, fingerprint, card swiping, etc. A suitable door opening manner may be selected according to an actual case. The door lock likewise supports a plurality of alarm manners, and alarms are issued for cases where unlocking settings are not met. In simple terms, the door lock may also be locked with a special tool lock, which can only be opened by professional technicians with professional unlocking tools. For example, a push bar lock is configured on an inner side of the door lock to meet emergency escape needs.

As shown in FIGS. 1 and 3, part of the first side heat dissipation long edge 110 corresponding to the power distribution cabinet 310 of the device row 400 is further provided with a protective wall 801, and the shutters (and/or the dustproof mesh) are disposed corresponding to the position of the rack 200, ensuring that external wind enters the container body 100 through the shutters (and/or the dustproof mesh), while avoiding moisture or sunlight from damaging the power distribution cabinet 310. As shown in FIG. 1, the protective wall 801 is disposed between adjacent shutters (and/or dustproof meshes). The protective wall 801 is made of, for example, a steel plate and the corner post. Part of the protective wall 801 may be added with transverse and longitudinal reinforcing ribs to improve the overall strength of the container body 100, enhance the resistance of the container body 100 to deformation and extrusion, and reduce the possibility of damage during loading, unloading and transportation.

Further, a top of the protective wall 801 has a cable inlet 802 disposed corresponding to a top end of the power distribution cabinet 310.

Further, a water curtain structure is mounted on the outer side of the first side heat dissipation long edge 110, so that air outside the container body 100 enters into the cavity through a wet curtain with strong water absorption, water on the wet curtain evaporates under an adiabatic state to remove a large amount of latent heat, the purified, cooled and oxygenated cold air is sent into the container body 100, and through continuous convection, the heat dissipation effect is further improved.

During transportation, the water curtain structure is stored in the container body 100 through a water curtain storage structure. For example, the water curtain storage structure for fixing the water curtain is disposed on an inner side of the protective wall 801. The water curtain storage structure may be a hook, a rope ring, a clamping groove, and the like. When in use, the water curtain cooling mechanism is taken out from the container body 100 and mounted on an outer side of the dustproof mesh and/or shutter and/or water curtain structure along the first side heat dissipation long edge 110.

The separate container 1 of some embodiments of the present application further includes an accessory box fixed inside the container body 100 for loading necessary accessory facilities such as awnings, awning fixings, water curtain pipelines, communication pipelines, and the like.

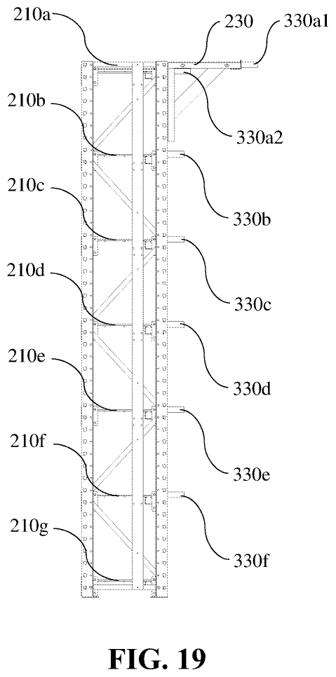

As shown in FIGS. 2 and 19, the rack 200 in the separate container 1 has a plurality of partition layers for placing the servers. A distance between the partition layers corresponds to a height of an upright server. That is to say, the servers are arranged upright on the partition layers of the rack 200. A space at the top of the rack 200 up to the top of the container body 100 is not enough to accommodate an upright server device. In order to improve the computing power of the separate container server device, increasing the number of servers is an effective way to achieve enhanced computing power while ensuring the computing power of a single server.

In some embodiments of the present application, an extension baffle 230 is provided to extend a length of a partition plate 210 at an uppermost layer of the rack 200 along the width direction of the container body 100, so that the server can be laid flat thereon, which increases the number of integrated servers and can improve the computing power of the separate container server device. Of course, in a case where the top space allows, the server located at the topmost layer may be normally arranged upright.

The electric control system includes a plurality of power distributors. There are two power distributors on the partition plate at the topmost layer of the rack 200, one of which is connected with the server on the partition plate at the topmost layer of the rack 200, and the other of which is connected with a server on a partition plate at a layer directly below the same. The servers on the remaining partition plates are connected with the power distributors on the partition plates at respective upper layers.

Taking the rack 200 shown in FIG. 19 as an example, the rack 200 has 7 partition plates 210a to 210g from top to bottom, wherein the partition plate 210a is located at a topmost layer, and the partition plate 210g is located at a bottommost layer. Servers are separately arranged and disposed on the partition plates 210a to 210g. The extension baffle 230 is extended on and connected to the topmost-layer partition plate 210a. An outer side of the extension baffle 230 is connected with a power distributor 330a1, and an outer side of the topmost-layer partition plate 210a is connected with a power distributor 330a2. In addition, an outer side of the partition plate 210b is connected with a power distributor 330b, an outer side of the partition plate 210c is connected with a power distributor 330c, an outer side of the partition plate 210d is connected with a power distributor 330d, an outer side of the partition plate 210e is connected with a power distributor 330e, an outer side of the partition plate 210f is connected with a power distributor 330f, and an outer side of the partition plate 210g is not connected with a power distributor.

The servers arranged and disposed on the partition plate 210g are connected with the power distributor 330f at an upper layer, the servers arranged and disposed on the partition plate 210f are connected with the power distributor 330e at an upper layer, the servers arranged and disposed on the partition plate 210e are connected with the power distributor 330d at an upper layer, the servers arranged and disposed on the partition plate 210d are connected with the power distributor 330c at an upper layer, the servers arranged and disposed on the partition plate 210c are connected with the power distributor 330b at an upper layer, the servers arranged and disposed on the partition plate 210b are connected with the power distributor 330a2 at an upper layer, and the server arranged and disposed on the partition plate 210a is connected with the power distributor 330a1. Each power distributor is configured with an independent switch, which is safe and reliable.

That is to say, the partition plates below the topmost-layer partition plate form “up-down” connection relationships in which a power distributor on an upper-layer partition plate is connected to servers on a lower-layer partition plate, so that there is no need to mount a power distributor on the partition plate closest to the bottom plate of the container body. This is not only convenient to operate, but also can reduce damage to the power distributors caused by moisture and stains in the container body 100 and the risk of short circuit.

In related technologies, each power distributor is provided with the switch to control power on or off. In some embodiments, the power distribution cabinet 310 is provided with a switch module for controlling each power distributor, and the switch module achieves independent control of each power distributor. For example, the switch module controls the power on or off of each power distributor. When a certain power distributor needs to be maintained or servers connected to a certain power distributor need to be powered off for maintenance, it is only necessary to use the switch module to power off the power of the power distributor alone, which facilitates maintenance and improves safety. Furthermore, since the switch modules are centrally provided in the distribution cabinet, the centralized control of all the power distributors can be achieved, which is convenient for operation. For example, when a plurality of power distributors need to be turned off or on, there is no need to separately walk near the respective power distributors for operation.

The partition plate at each layer of the rack 200 is made into a mesh shape, for example, to facilitate observation of a working status of the servers at each partition layer.

As shown in FIGS. 3 and 19, in order to enhance the overall strength of the rack 200, in an embodiment of the present application, the topmost-layer partition plate 210a and the extension baffle 230 are in the shape of a plate body, and the staff cannot be timely aware of a working status of the servers located on the topmost-layer partition plate 210a during maintenance. The separate container server device of some embodiments of the present application further includes a top-layer device status feedback means for feeding back a top-layer device status. The top-layer device status feedback means is implemented in various ways such as software monitoring, hardware monitoring, remote monitoring and log monitoring.

In an embodiment of the present application, the top-layer device status feedback means employs a reflective mirror observation means, which can achieve real-time monitoring of the server status by means of a status indicator light of the server itself without investing any software or hardware in the server. The reflective mirror observation means is connected to the server disposed on the corresponding topmost-layer partition plate 210a in the container body 100.

The reflective mirror observation means includes a plurality of feedback areas, each corresponding to at least one server disposed on the topmost-layer partition plate 210a for feeding back a working status of the at least one server. There may be one or more reflective mirror observation means, which feeds back the working status of each server in real time, facilitating timely processing by the staff and ensuring the working efficiency of the device.

In other embodiments, the topmost-layer partition plate 210a and the extension baffle 230 may likewise be made into a mesh shape to facilitate monitoring of their status by the staff. In this case, the provision of the top-layer device status feedback means may be canceled.

In some embodiments, the server cluster container 1 includes a top partition plate and a top corrugated plate that are disposed oppositely, with a top wiring conduit located between the top partition plate and the top corrugated plate. The top partition plate provides concealment and protection for the top wiring conduit. In some embodiments, an upper side of the top partition plate is further provided with a heat-insulating layer for isolating external heat from entering an area below the top partition plate. The heat-insulating layer employs heat-insulating materials. Further, a foaming material, such as a polyurethane foaming material, is filled between the heat-insulating layer and the top corrugated plate to further enhance the heat insulation effect.

A separately containerized server device of some embodiments of the present application can effectively shorten the device system construction period and improve the reliability of system operation through modular and integrated design. Some embodiments of the present application integrate five systems of structure, power distribution, HVAC, network, and intelligence, so that each separate container is a complete functional unit. The single separate container can not only be delivered and operate independently, but also can operate in multiple combination to meet different needs.

In summary, a method for mounting a separately containerized server device of some embodiments of the present application includes the following steps:

unloading a separate container 1 from a standard container 2;

mounting a plurality of servers on a rack 200; and

connecting the plurality of servers to an electric control system.

The plurality of separate containers 1 are mated along the length direction of the container bodies 100, and the adjacent separate containers 1 are connected.

Movable walls of the separate containers 1 that are mated are opened to make the maintenance passages 500 of the separate containers 1 in communication. When the environment requires, fans 910 of a cooling structure 900 can also be pulled out from inside of the container body 100 to outside of container body 100 to make the fans 910 external.

Of course, the present application may have many other embodiments. Without departing from the spirit and essence of the present application, those skilled in the art may make various corresponding changes and modifications according to the present application, but these corresponding changes and modifications should all fall within the scope of protection of the attached claims of the present application.

### INDUSTRIAL APPLICABILITY

The separate container of the present application includes the container body having the connecting portion for connecting two adjacent separate containers, the connecting portion including the plurality of length connecting components located at an end along the length direction of the container body, and/or the connecting portion includes the plurality of height connecting components located at an end along the height direction of the container body. The separately containerized server device of the present application includes the plurality of servers and the above separate container, and the servers are arranged and disposed on the rack and connected to the electric control system. The present application meets different requirements of users for the size, scale and computing power of containerized servers based on different geographical conditions and power allocations in each usage region, as well as different purposes and usage times of the users, or to meet changing requirements at different time periods, resulting the simple structure and high adaptability.

1. A separate container, comprising a container body having a connecting portion for connecting two adjacent separate containers.

2. The separate container according to claim 1, wherein the connecting portion comprises a plurality of length connecting components located at an end along a length direction of the container body, and/or the connecting portion comprises a plurality of height connecting components located at an end along a height direction of the container body.

3. The separate container according to claim 1, wherein the container body is provided with a communication port in communication with another container body disposed adjacently;
wherein the communication port is located at an end along the length direction and/or height direction of the container body, and the communication port is provided with a movable wall;
wherein the movable wall comprises a door and/or a detachable wall panel; and
wherein the communication port is at an entire end position of the container body along the length direction.

4-6. (canceled)

7. The separate container according to claim 1, wherein the connecting portion comprises a container corner member; and
wherein an external size of length, width and height of the container body is smaller than a size of an internal space of a standard container, and the container body can be integrally loaded in the standard container.

8. (canceled)

9. The separate container according to claim 7, wherein a first gap and a second gap are present between left and right side walls of the container body along the length direction and left and right inner walls of the standard container along the length direction, when the container body is loaded in the standard container;
wherein a sum of the first gap and the second gap is 90±20 mm;
wherein a third gap and a fourth gap are respectively present between front and rear side walls of the container body along a width direction and front and rear inner walls of the standard container along the width direction;
wherein a sum of the third gap and the fourth gap is 90±20 mm;
wherein a fifth gap is present between a top wall of the container body and a top inner wall of the standard container; and
wherein the fifth gap is 40±10 mm.

10-14. (canceled)

15. A separate container, comprising a container body, a rack and an electric control system, the rack and the electric control system being respectively fixed in the container body, and the container body having a connecting portion for connecting two adjacent separate containers.

16. The separate container according to claim 15, wherein the connecting portion comprises a plurality of length connecting components located at an end along a length direction of the container body, and/or the connecting portion comprises a plurality of height connecting components located at an end along a height direction of the container body.

17. The separate container according to claim 15, wherein the container body is provided with a communication port in communication with another container body disposed adjacently;
wherein the communication port is at an entire end position of the container body along the length direction;
wherein the communication port is located at an end along the length direction of the container body, and the communication port is provided with a movable wall; and
wherein the movable wall comprises a door and/or a detachable wall panel.

18-19. (canceled)

20. The separate container according to claim 17, wherein the container body is provided with a maintenance passage, and an end of the container body in the length direction corresponding to the maintenance passage is provided with the movable wall.

21. The separate container according to claim 17, wherein the communication port is located at an end along the height direction of the container body, and the communication port is provided with a movable wall;
wherein a maintenance passage is disposed in the container body, and a position in a container top and/or container bottom of the container body corresponding to an end of the maintenance passage is provided with the movable wall;
wherein the movable wall comprises a door and/or a detachable wall panel; and
wherein the communicating port is provided with a ladder.

22-24. (canceled)

25. The separate container according to claim 20, wherein the electric control system is used for connecting with servers carried by the rack, and the electric control system comprises a power distribution cabinet, the rack and the power distribution cabinet are disposed in a row along the length direction of the container body to form a device row, and the maintenance passage is formed between the device row and a side wall of the container body; and
wherein positions of two side walls of the container body along the width direction not corresponding to the maintenance passage are fixed side walls.

26. (canceled)

27. The separate container according to claim 15, wherein the connecting portion comprises a container corner member; and
wherein an external size of length, width and height of the container body is smaller than a size of an internal space of a standard container, and the container body can be integrally loaded in the standard container.

28. (canceled)

29. The separate container according to claim 27, wherein a first gap and a second gap are present between left and right side walls of the container body along the length direction and left and right inner walls of the standard container along the length direction, when the container body is loaded in the standard container;
wherein a sum of the first gap and the second gap is 90±20 mm;
wherein a third gap and a fourth gap are respectively present between front and rear side walls of the container body along a width direction and front and rear inner walls of the standard container along the width direction;
wherein a sum of the third gap and the fourth gap is 90±20 mm;
wherein a fifth gap is present between a top wall of the container body and a top inner wall of the standard container; and
wherein the fifth gap is 40±10 mm.

30-34. (canceled)

35. The separate container according to claim 25, wherein the container body comprises a first side heat dissipation long edge and a second side heat dissipation long edge that are disposed oppositely, the first side heat dissipation long edge is provided with a dustproof mesh and/or shutters and/or a water curtain structure, the second side heat dissipation long edge is provided with a cooling structure, and the maintenance passage is disposed between the device row and the first side heat dissipation long edge.

36. The separate container according to claim 35, wherein the cooling structure is disposed corresponding to a position of the rack, and a position on the second side heat dissipation long edge corresponding to the power distribution cabinet is provided with a maintenance door; and
wherein the cooling structure comprises a fan and a fan mounting frame, and the fan is mounted to the container body through the fan mounting frame.

37. (canceled)

38. The separate container according to claim 36, wherein the fan mounting frame comprises a connecting framework connected to the container body and a supporting frame detachably connected to an inner side or outer side of the connecting framework through a plurality of fasteners, and the fan is disposed on the supporting frame;
wherein the connecting framework is further partially connected to a corner post of the container body; and
wherein the connecting framework is connected to at least one of a top side beam, a bottom side beam, and a corner post of the container body.

39. (canceled)

40. The separate container according to claim , wherein the supporting frame comprises a fixing portion for detachably connecting the connecting framework through a fastener and a supporting portion for supporting the fan;
wherein the supporting frame comprises a limiting portion for limiting displacement of the fan; and
wherein the supporting frame is bent from a metal plate and machined to form the fixing portion, the supporting portion and the limiting portion.

41-43. (canceled)

44. The separate container according to claim 35, wherein a position on the first side heat dissipation long edge corresponding to the power distribution cabinet is provided with a protective wall, and a position on the first side heat dissipation long edge corresponding to the rack is provided with the dustproof mesh and/or the shutters and/or the water curtain structure; and
wherein the separate container further comprises a water curtain storage structure for storing the water curtain structure, and the water curtain storage structure is located in the container body.

45. (canceled)

46. A separately containerized server device, comprising a plurality of servers, wherein the separately containerized server device further comprises a plurality of separate containers according to claim 15, and the servers are arranged and disposed on the rack and connected to the electric control system.

47-49. (canceled)

50. The separately containerized server device according to claim 46, wherein a sealing structure is disposed in a slit between two adjoining separate containers along the length direction of the container bodies.
